(19) United States
(12) Patent Application Publication
(10) Pub. No.: US 2017/0131326 A1
(43) Pub. Date: May 11, 2017

(54) PULSED CURRENT SOURCE WITH INTERNAL IMPEDANCE MATCHING

(71) Applicant: QualiTau, Inc., Mountain View, CA (US)

(72) Inventor: Jens ULLMANN, San Jose, CA (US)

(21) Appl. No.: 14/937,297

(22) Filed: Nov. 10, 2015

(51) Int. Cl. G01R 1/30; G01R 31/28

(52) U.S. Cl. CPC G01R 1/30; G01R 31/2858

(57) ABSTRACT

Pulsed current circuitry for electromigration testing of semiconductor integrated circuits and components. The circuit includes a multiplexer that outputs analog voltage pulses, and is capable of generating both bipolar and unipolar voltage pulses. At least one operational amplifier and resistor receive the voltage pulses from the multiplexer and convert the voltage pulses to current pulses. A charge booster circuit is provided for minimizing overshoots and undershoots during transitions between current levels in the test circuit.

### BACKGROUND

The present invention relates generally to circuitry for testing electrical components and circuits. More particularly, the present invention relates to current pulse circuitry for use in electromigration testing of semiconductor integrated circuits and components.

Semiconductor reliability tests require continuous application of electrical stimulus, usually at a controlled temperature ranging from −50° C. to +350° C. based on the specific test parameter (e.g., hot carrier, electromigration, etc.). For electromigration testing in particular, testing using DC current has always been the preferred approach due to its simplicity, built-in conservatism, and relatively low cost. However, advances in process miniaturization have rendered DC tests insufficient, thus making similar testing under pulsed conditions a necessity.

Current pulses are thus often employed in testing electrical components and circuits. An ideal pulsed stimulus should allow flexible control of Pulse-Repetition-Rate, Duty-Cycle, Polarity, and Intensity (Amplitude). These parameters are illustrated in FIGS. 1A and 1B, where T is the period, frequency (f) is the pulse repetition rate (Hz), duty cycle is 2 tp/T; positive amplitude is Aₚ, and negative amplitude is Aₙ (Volt, Amp). When high repetition rate current pulses are required, for example with pulsed electromigration tests, the desired pulse is typically rectangular. Therefore, the transition between current levels must be abrupt with minimal overshoot to effectively provide the intended current drive at each level. FIGS. 1A and 1B show the transition between current levels for bipolar and unipolar current pulses, respectively. Ideally, the transition from the “DC Level” (frequently “GND”) to the required current (“Aₚ” or “Aₙ,” or generally “A” for simplicity) is abrupt, as shown in FIGS. 1A and 1B.

In reality, however, such transitions take time and can be too slow to reach the required maximum current level A. An effective technique to achieve current pulses is implemented by using two constant current (DC) sources and charge booster circuit, as described in U.S. Pat. No. 6,249,137 to Krieger et al., entitled “CIRCUIT AND METHOD FOR PULSED RELIABILITY TESTING” and in U.S. Pat. No. 7,049,713 to Cuevas et al., entitled “PULSED CURRENT GENERATOR CIRCUIT WITH CHARGE BOOSTER.” However, using this technique has become difficult due to its dependence on discrete and potentially obsolete transistors. In addition, aggressive semiconductor scaling has been pushing down pulse current levels, making it difficult to eliminate pulse overshoots. The relatively large number of discrete components in the circuit, combined with its complex calibration and adjustment, increase manufacturing and maintenance costs. Therefore, it is desirable to provide a high quality pulse current source that can achieve the desired current pulses as well as overcome the limitations discussed above.

### SUMMARY

In accordance with an embodiment, a test circuit is provided for applying current pulses to a device under test (DUT). The test circuit includes a multiplexer and at least one operational amplifier and resistor. The multiplexer outputs analog voltage pulses, and is capable of generating both bipolar and unipolar voltage pulses. The at least one operational amplifier and resistor receive the voltage pulses from the multiplexer and convert the voltage pulses to current pulses. An operational amplifier outputs current pulses, and the current pulses are bipolar or unipolar current pulses depending on whether the operational amplifier and resistor receive bipolar or unipolar voltage pulses.

In accordance with another embodiment, a method is provided for providing a pulsed current to a device under test (DUT). A plurality of different voltage levels are provided to a plurality of input terminals of a multiplexer. Voltage pulses are generated from a selected voltage level by using input select combination of input select lines of the multiplexer to determine which of the input terminals of the multiplexer is connected to an output of the multiplexer. Input select combination of the multiplexer is performed by assigning address values to input select lines of the multiplexer in a way such that any transitional address value leads to a monotonic change of the output of the multiplexer, which comprise voltage pulses. The voltage pulses are converted to current pulses using a plurality of resistors, operational amplifiers, and capacitors

In accordance with yet another embodiment, a single circuit that is capable of providing both unipolar and bipolar current pulses is provided. The circuit includes a multiplexer and at least one operational amplifier and resistor. The muiltiplexer receives at least one positive voltage signal and at least one negative voltage signal, and the multiplexer is capable of generating both bipolar and unipolar voltage pulses from the voltage signals it receives. The operational amplifier and resistor receive the voltage pulses from the multiplexer and convert the voltage pulses to current pulses. An operational amplifier outputs bipolar or unipolar current pulses depending on whether the at least one operational amplifier and resistor receive bipolar or unipolar voltage pulses.

In accordance with another embodiment, a method is provided for using a charge booster circuit for minimizing overshoots and undershoots during transitions between current levels in a test circuit for applying current pulses to a device under test (DUT). The test circuit is provided and includes a charge booster circuit, the charge booster circuit comprising at least one operational amplifier, a resistor network, and a capacitor. Current pulses are input to the charge booster circuit. A charge flowing through the capacitor is controlled using the resistor network to match a charge needed to bring the voltage across a parasitic capacitor of the test circuit to provide an output of the charge booster circuit. The output of the charge booster circuit is then delivered to the DUT.

### BRIEF DESCRIPTION OF THE DRAWINGS

The invention, together with further objects and advantages thereof, may best be understood by reference to the following description taken in conjunction with the accompanying drawings in which:

FIGS. 1A and 1B illustrate bipolar pulses and unipolar pulses, respectively, that are useful in testing electronic components.

FIG. 2 is a conceptual schematic diagram of pulsed current circuitry in accordance with an embodiment.

FIG. 3 is a conceptual schematic diagram of a charge booster circuit in accordance with an embodiment.

FIG. 4 is a conceptual schematic diagram of another embodiment of a charge booster implementation using banks of resistors for R₆ and Rₓ.

FIG. 5 is a conceptual schematic diagram of a pulsed current source and a charge booster circuit, in accordance with an embodiment.

FIG. 6 is a flow chart of a method of providing a pulsed current to a device under test (DUT).

### DETAILED DESCRIPTION OF EMBODIMENTS

The present invention relates generally to testing electrical components and circuits. The embodiments herein describe pulsed current circuitry for electromigration testing of semiconductor integrated circuits and components.

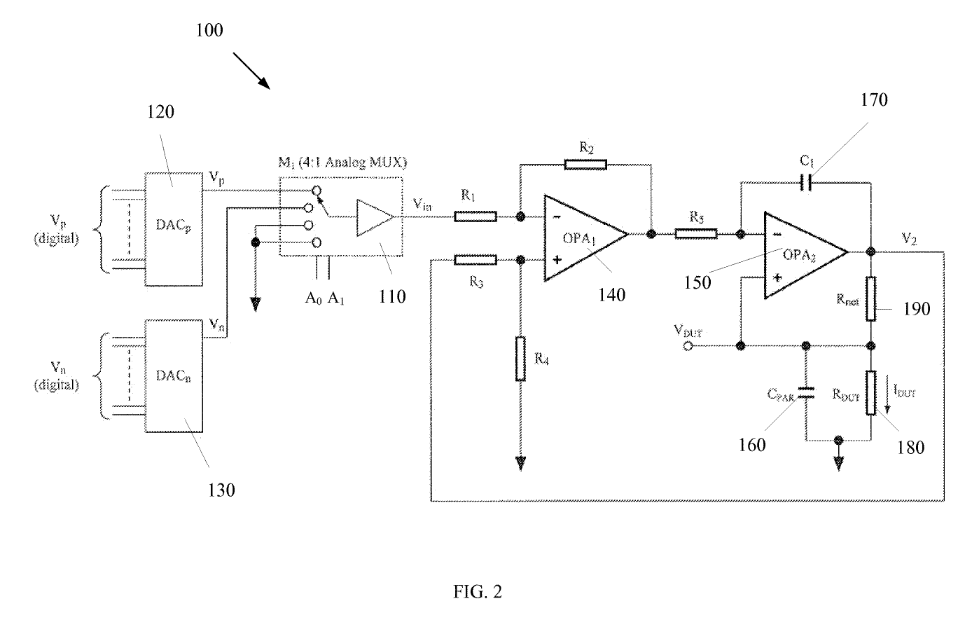

Referring to FIGS. 2-5, embodiments of pulsed current test circuitry will be described. FIG. 2 is a conceptual schematic diagram of pulsed current test circuitry 100 in accordance with an embodiment. In the illustrated embodiment, the pulsed current test circuitry 100 includes a high-speed analog multiplexer 110. An exemplary multiplexer is the ADV3221/ADV3222 analog multiplexer, which is available commercially from Analog Devices, Inc. of Norwood, Mass. The multiplexer 110 can generate either unipolar or bipolar voltage pulses at repetition rates as high as 10 MHz (40 nS pulse). The rest of the circuit 100 converts these voltage pulses (Vᵢₙ) to current pulses (I_{dut}) accordingly, using fast operational amplifiers, which function properly at these rates.

The sensitivity of the circuit 100 to common-mode errors is minimized by positioning the device under test (DUT) between ground and the output of the current source. Another advantage is attained by not using a differential amplifier, which is commonly associated with high leakage currents.

DACₚ 120 and DACₙ 130 are digital-to-analog converters that convert a digital voltage signal to an analog voltage signal. The DACₚ 120 and DACₙ 130 provide the required discrete analog voltage levels Vₚ and Vₙ to the second and third input terminals of the analog multiplexer M₁ 110, respectively. That is, Vₚ and Vₙ should be sufficient to drive the desired current through R_{DUT}. The first input terminal of the multiplexer M₁ 110 is connected to ground voltage GND or to an additional digital-to-analog converter (DAC_{g}) to have control over a desired DC component added to current pulse. In Example 1 below with three voltage levels, the fourth input of the multiplexer M₁ 110 is still used and is connected to the first input to achieve monotonic change of output even though only three voltage levels are needed for a bipolar pulse in this example.

Generally, the multiplexer M₁ 110 has one less input select line than voltage levels, as shown in the examples below. In Example 1, the two input select lines A₀ and A₁ determine which of the inputs of the multiplexer M₁ 110 is connected to the output of the multiplexer M₁ 110 (Vin). As explained herein, the particular connectivity is intentional rather than arbitrary, with the second input connected to the highest maximum voltage (Vₚ in this example), the first and fourth inputs connected to the intermediate (GND or DAC_{g}, if applicable), and the third input connected to the lowest voltage (Vₙ).

Input select combination of multiplexer M₁ 110 by assigning address values to the input select lines A₀ and A₁ is performed in a way such that any transitional address value always leads to a monotonic, and therefore seamless, change of the output (e.g., high=>low=>lower; low=>high=>higher), with the following example demonstrating it in more detail:

### Example 1: Bipolar Pulse (Three Voltage Levels)

| | | M₁ Output Status |
|---|---|---|
| M₁ Output Voltage | Input Select (Address) | (Stable/Transitional) |
| Vₚ | A₀ = 0, A₁ = 1 | Stable |
| V_{g} | A₀ = 0, A₁ = 0 | Stable |
| V_{g} | A₀ = 1, A₁ = 1 | Transitional |
| Vₙ | A₀ = 1, A₁ = 0 | Stable |

As shown in the example above, only one address line changes during transitions from Vₚ to V_{g} and from Vₙ to V_{g}. However, if a transition from Vₚ to Vₙ takes place, assigning the input select as A₀=1 and A₁=1 as a transitional address of V_{g} ensures that no matter which address line changes state first—the output voltage of the MUX M₁ 110 follows the desired voltage transition monotonically. It will be understood that, in other embodiments, the three-level case described above can be expanded to four- and five-level pulse, with monotonic transitions ensured, using a similar addressing approach with three and four input select lines, respectively, as shown in the examples below.

### Example 2: Bipolar Pulse (Four Voltage Levels)

| | | M₁ Output Status |
|---|---|---|
| M₁ Output Voltage | Input Select (Address) | (Stable/Transitional) |
| V₁ (max) | A₀ = 0, A₁ = 0, A₂ = 1 | Stable |
| V₂ (V₃ < V₂ < V₁) | A₀ = 0, A₁ = 0, A₂ = 0 | Transitional |
| V₂ (V₃ < V₂ < V₁) | A₀ = 0, A₁ = 1, A₂ = 1 | Transitional |
| V₂ (V₃ < V₂ < V₁) | A₀ = 0, A₁ = 1, A₂ = 0 | Stable |
| V₃ (V₄ < V₃ < V₂) | A₀ = 1, A₁ = 1, A₂ = 1 | Stable |
| V₃ (V₄ < V₃ < V₂) | A₀ = 1, A₁ = 1, A₂ = 0 | Transitional |
| V₃ (V₄ < V₃ < V₂) | A₀ = 1, A₁ = 0, A₂ = 1 | Transitional |
| V₄ (min) | A₀ = 1, A₁ = 0, A₂ = 0 | Stable |

In Example 2 above, in the transition from V₁ to V₄, there are two input select lines changing state: A₂ from 1 to 0 and A₀ from 0 to 1. If A₂ transitions before A₀, the resulting transitional pattern is 000, which is assigned to V₂. If, on the other hand, A₀ transitions before A₂A₀, the resulting transitional pattern is 101, which is assigned to V₃. Therefore, the resulting voltage change is monotonic while the address pattern is changing.

### Example 3: Bipolar Pulse (Five Voltage Levels)

| | | M₁ Output Status |
|---|---|---|
| | | (Stable/ |
| M₁ Output Voltage | Input Select (Address) | Transitional) |
| V₁ (max) | A₀ = 0, A₁ = 0, A₂ = 1, A₃ = 1 | Stable |
| V₂ (V₃ < V₂ < V₁) | A₀ = 0, A₁ = 0, A₂ = 1, A₃ = 0 | Transitional |
| V₂ (V₃ < V₂ < V₁) | A₀ = 1, A₁ = 0, A₂ = 1, A₃ = 1 | Transitional |
| V₂ (V₃ < V₂ < V₁) | A₀ = 0, A₁ = 0, A₂ = 0, A₃ = 1 | Stable |
| V₂ (V₃ < V₂ < V₁) | A₀ = 0, A₁ = 1, A₂ = 1, A₃ = 1 | Transitional |
| V₃ (V₄ < V₃ < V₂) | A₀ = 1, A₁ = 0, A₂ = 1, A₃ = 0 | Transitional |
| V₃ (V₄ < V₃ < V₂) | A₀ = 0, A₁ = 1, A₂ = 0, A₃ = 1 | Transitional |
| V₃ (V₄ < V₃ < V₂) | A₀ = 1, A₁ = 1, A₂ = 1, A₃ = 1 | Transitional |
| V₃ (V₄ < V₃ < V₂) | A₀ = 0, A₁ = 0, A₂ = 0, A₃ = 0 | Stable |
| V₃ (V₄ < V₃ < V₂) | A₀ = 0, A₁ = 1, A₂ = 1, A₃ = 0 | Transitional |
| V₃ (V₄ < V₃ < V₂) | A₀ = 1, A₁ = 0, A₂ = 0, A₃ = 1 | Transitional |
| V₄ (V₅ < V₄ < V₃) | A₀ = 1, A₁ = 0, A₂ = 0, A₃ = 0 | Transitional |
| V₄ (V₅ < V₄ < V₃) | A₀ = 1, A₁ = 1, A₂ = 0, A₃ = 1 | Transitional |
| V₄ (V₅ < V₄ < V₃) | A₀ = 0, A₁ = 1, A₂ = 0, A₃ = 0 | Stable |
| V₄ (V₅ < V₄ < V₃) | A₀ = 1, A₁ = 1, A₂ = 1, A₃ = 0 | Transitional |
| V₅ (min) | A₀ = 1, A₁ = 1, A₂ = 0, A₃ = 0 | Stable |

Thus, as shown above, with every change of a single address line, the next voltage is selected. For example, transitioning from V₂ to V₅, the voltages V₃, V₄, and V₅ will always be selected in that order (i.e., monotonic changes), with no gaps or duplicate voltage selections.

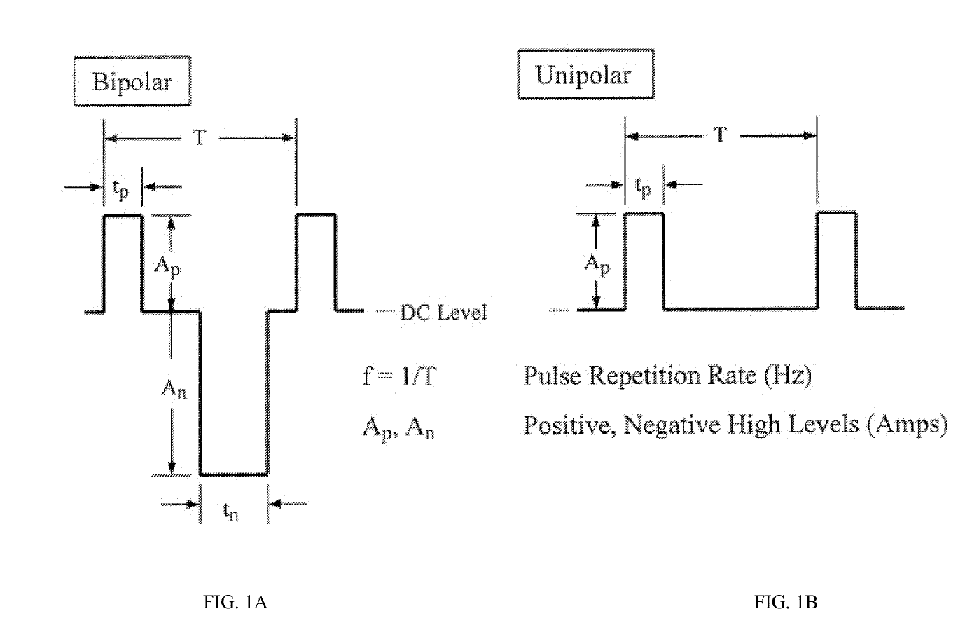

Assuming that the parasitic capacitance Cₚₐᵣ 160 and capacitor C₁ 170 are very small (R₅*C₁ is less than one percent of Tₚ or Tₙ; and Rₙₑₜ*Cₚₐᵣ is less than one percent of Tₚ or Tₙ), their charging and discharging will take much less time than tₚ and tₙ (FIG. 1). Given that, the current I_{DUT} flowing through R_{DUT} 180 is the same as the current flowing through Rₙₑₜ 190, and the following relation is valid:

$$( {V}_{DUT} + {I}_{DUT} {R}_{net} ) ( \frac{{R}_{4}}{{R}_{3} + {R}_{4}} ) - {V}_{off}^{1} = \frac{{V}_{DUT} - {V}_{off}^{2} - {V}_{i n}}{{R}_{1} + {R}_{2}} {R}_{1} + {V}_{i n} \qquad ( 1 )$$

where V_{off}¹ and V_{off}² are the offset voltages of the operational amplifiers OPA₁ 140 and OPA₂ 150, respectively. It will be understood that input bias currents are ignored because they are too small to have any significant effect on the circuit 100.

Combining and arranging terms in equation (1) above yields:

$${V}_{DUT} ( \frac{{R}_{1}}{{R}_{1} + {R}_{2}} - \frac{{R}_{4}}{{R}_{3} + {R}_{4}} ) + {V}_{i n} \frac{{R}_{2}}{{R}_{1} + {R}_{2}} - {V}_{off}^{2} \frac{{R}_{1}}{{R}_{1} + {R}_{2}} + {V}_{off}^{1} == {I}_{DUT} {R}_{net} \frac{{R}_{4}}{{R}_{3} + {R}_{4}} \qquad ( 2 )$$

By setting R1=R2 and R3=R4, the terms of V_{DUT} vanish and equation (2) can be simplified to:

$$\begin{matrix}\frac{{V}_{i n}}{2} - \frac{{V}_{off}^{2}}{2} + {V}_{off}^{1} = \frac{{I}_{DUT} {R}_{net}}{2} & ( 3 ) \\ and & \\ {I}_{DUT} = \frac{{V}_{i n}}{{R}_{net}} + \frac{2 {V}_{off}^{1} - {V}_{off}^{2}}{{R}_{net}} = \frac{{V}_{i n}}{{R}_{net}} + δ & ( 4 )\end{matrix}$$

where error

$$δ ≡ \frac{2 {V}_{off}^{1} - {V}_{off}^{2}}{Rnet}$$

Apart from the error introduced by the offset voltages, the required current pulse is attained by setting DACₚ and DACₙ to Vₚ=IₚRₙₑₜ and Vₙ=IₙRₙₑₜ, respectively. To assess the accuracy of the current source, the worst case error δₘₐₓ is defined as:

$$δ ≡ Max \{ \frac{2 {V}_{off}^{1} - {V}_{off}^{2}}{Rnet} \} \leq \frac{3}{Rnet}$$

where V_{off} (max) is the largest possible offset value of (V_{off}¹, V_{off}²) under the entire operating range (mainly temperature). The ratio between the maximum error and the desirable current provides a conservative gauge of accuracy for the pulsed current source:

$$Max Relative Error ( \% ) \leq \pm \frac{3 \vert {V}_{off} ( max ) \vert}{\vert {V}_{DUT} \vert} \qquad ( 5 )$$

This relative error can be a limitation for low currents. However, measurements are typically carried out in a controlled environment, where the ambient temperature varies only by a few degrees relative to the set room temperature. This enables nearly complete elimination of the error, using calibration, pre-test offset measurement, and common correction algorithms.

The circuit will not be complete as long as capacitor C₁ and Cₚₐᵣ are restricted to very low values. For C₁, which is connected to suppress high-frequency oscillations, it is not a real limitation because it functions effectively by increasing the pulse rise and fall times by a few nanoseconds only.

Cₚₐᵣ, on the other hand, poses a real challenge as its total value can reach 50 pF or more (combination of the packaged DUT, printed circuit board capacitance, and layout). For example, with R_{DUT}=1kΩ and Cₚₐᵣ=50 pF, the resulting time constant R_{DUT}Cₚₐᵣ is 50 nS (5×10⁻⁸ seconds), making low current pulses shorter than 250 nS practically impossible.

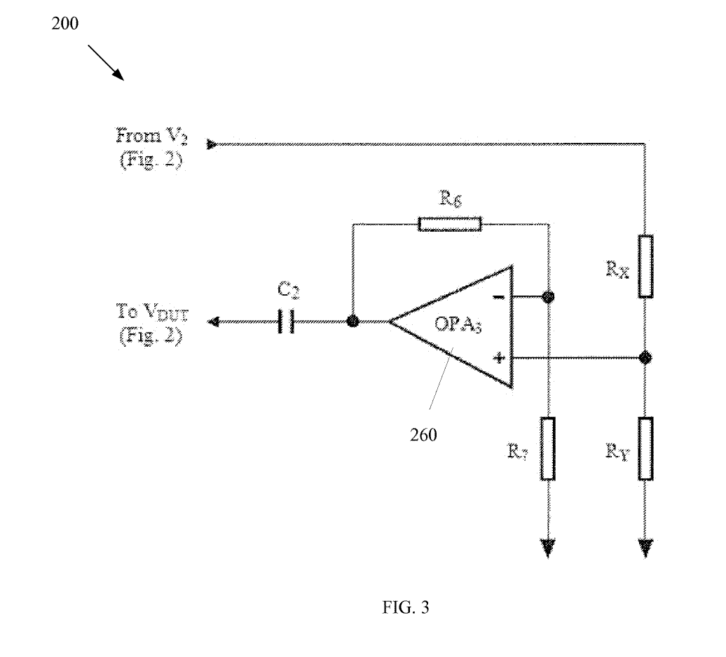

The solution involves a separate charge booster. Unlike U.S. Pat. No. 6,249,137, which uses discrete (and potentially obsolete) transistors and a relatively complex circuitry, according to an embodiment, a charge booster circuit 200, as shown in FIG. 3, is provided. This approach is based on the “balanced-attenuator” concept, which aims at eliminating overshoots and undershoots during abrupt changes, such as rise and fall of a pulse. The charge booster circuit 200 receives its input from the output of OPA₂ 150 of the pulsed current source (marked as V₂ in FIG. 2), and returns its output signal to the top of R_{DUT} (marked as “V_{DUT}” in FIG. 2). Similar to OPA₁ 140 and OPA₂ 150 (FIG. 2), operational amplifier OPA₃ 260 in the charge booster circuit 200 is sufficiently fast to function properly at the required pulse repetition rates.

As shown in FIG. 3, the charge booster circuit 200 is connected to the pulsed current source of FIG. 2 at two points. The charge booster circuit 200 receives its input from the output of OPA₂ 150, denoted as V₂, and delivers its output V_{DUT} to the DUT. Denoting the time just following a rise or fall (transition) of the pulse t=0⁺ and neglecting the offset voltage and input currents of OPA₂ 150, the current through capacitors C₂ and Cₚₐᵣ just after the transition satisfies the following relation:

$${V}_{DUT}^{{0}^{+}} = {V}_{2} ( \frac{{R}_{y}}{{R}_{x} + {R}_{y}} ) ( 1 + \frac{{R}_{6}}{{R}_{7}} ) ( \frac{{C}_{2}}{{C}_{2} + {C}_{par}} ) \qquad ( 6 )$$

Once the charge stored in the parasitic capacitor Cₚₐᵣ is stabilized at t=t^{stable}, the current flows only through the resistors, according to the following relation:

$${V}_{DUT}^{stable} = {V}_{2} ( \frac{{R}_{DUT}}{{R}_{DUT} + {R}_{net}} ) \qquad ( 7 )$$

If V_{DUT}⁰⁺=V_{DUT}^{stable}, the capacitors are charged at t=0⁺ to the “stable” level, meaning that the same current flows through Rₙₑₜ and R_{DUT}, with no overshoot or undershoot. Comparing the right hand side of equation (6) to the right hand side of equation (7):

$${V}_{2} ( \frac{{R}_{y}}{{R}_{x} + {R}_{y}} ) ( 1 + \frac{{R}_{6}}{{R}_{7}} ) ( \frac{{C}_{2}}{{C}_{2} + {C}_{par}} ) = {V}_{2} ( \frac{{R}_{DUT}}{{R}_{DUT} + {R}_{net}} ) \qquad ( 8 )$$

After cancellation of V₂ and rearranging terms, the following relation is obtained:

$$( 1 + \frac{{C}_{par}}{{C}_{2}} ) ( 1 + \frac{{R}_{x}}{{R}_{y}} ) = ( 1 + \frac{{R}_{6}}{{R}_{7}} ) ( 1 + \frac{{R}_{net}}{{R}_{DUT}} ) \qquad ( 9 )$$

Both sides of equation (9) are positive with minimum value greater than one, and no limit on their respective maximum value. Among the eight components (Cₚₐᵣ, C₂, Rₓ, R_{y}, R₆, R₇, Rₙₑₜ, and R_{DUT}) involved, Cₚₐᵣ and R_{DUT} are given (i.e., not adjusted by the system), while the value of Rₙₑₜ is based on the required currents in order to optimize both accuracy and compliance voltage. The remaining five components can be changed to meet equation (9). In fact, any set of two components, excluding (R₆, R₇) and (Rₓ, R_{y}), is sufficient, and the particular implementation depends on the applicable range of R_{DUT} and Cₚₐᵣ and the required accuracy. The use of continuous components, such as digital potentiometers and variable capacitors (varicap diodes), is not practical due to their limited range (varicap diode) and internal capacitance (digital potentiometer). Instead, the necessary variability is attained with banks of discrete components, selectively switched by their respective relays (or optical switches, if applicable).

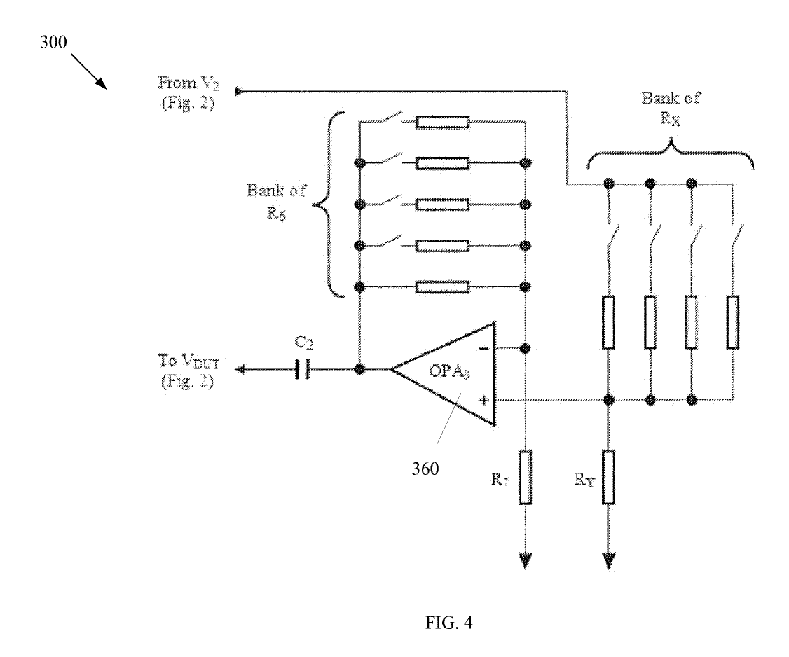

Another embodiment of a charge booster circuit 300 is shown in FIG. 4. In this embodiment, R₆ of the booster circuit 200 shown in FIG. 3 is replaced by a bank of four switched resistors and one fixed resistor (i.e., 16 possible values). The fixed resistor is added to avoid open loop when all switches are open. Similarly, Rₓ is replaced by another bank of four switched resistors (i.e., 15 possible values) to yield a total of 240 combinations.

In general, there are different ways to generate waveforms free of both overshoots and undershoots (satisfying equation (9)) by using combinations of switched components (e.g., C₂ and Rₓ, C₂ and R₆, etc.). Each such combination defines a different embodiment of the same idea.

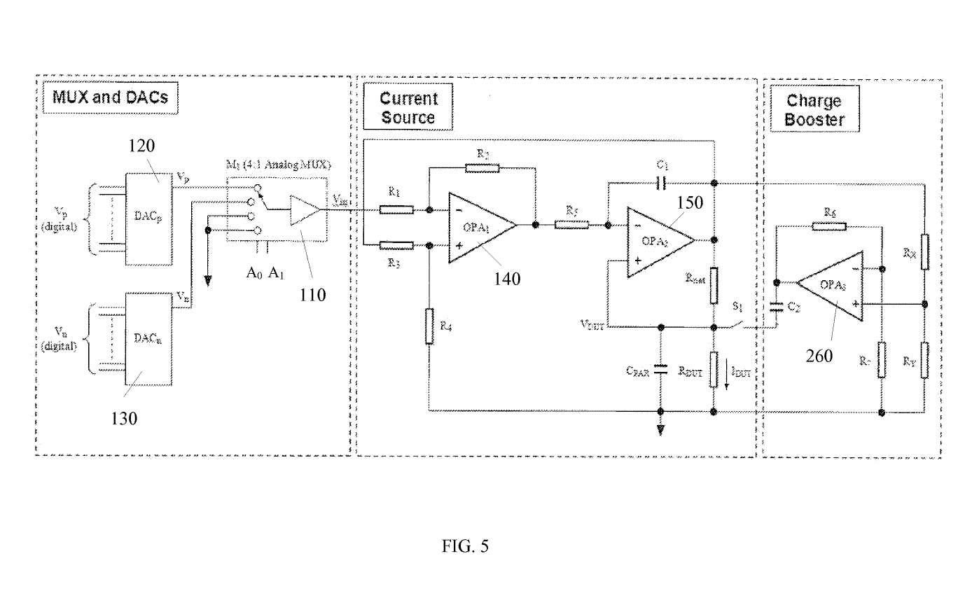

FIG. 5 shows an embodiment of a current source and a charge booster. In FIG. 5, each bank of devices is shown as a single variable component for simplicity.

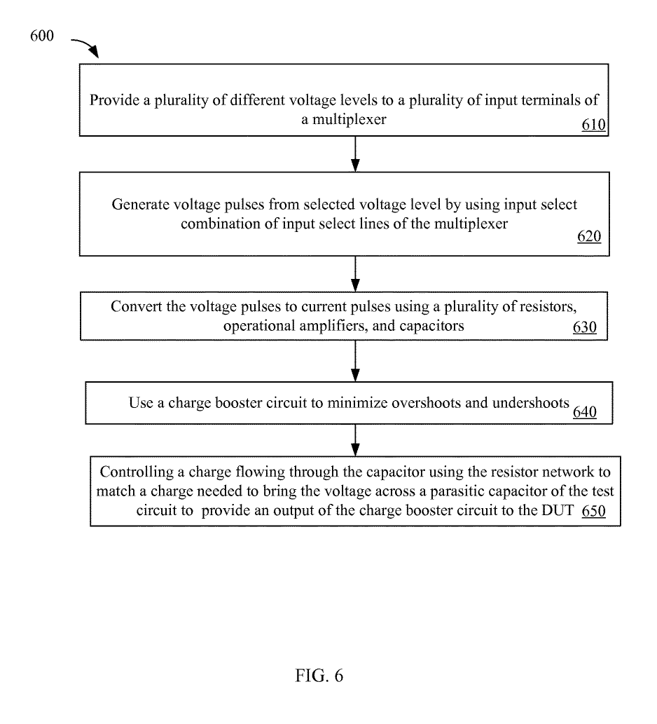

FIG. 6 is a flow chart of a method 600 of providing a pulsed current to a device under test (DUT). In Step 610, a plurality of different voltage levels is provided to a plurality of input terminals of a multiplexer. In Step 620, voltage pulses are generated from a selected voltage level by using input select combination of input select lines of the multiplexer to determine which of the input terminals of the multiplexer is connected to an output of the multiplexer. The input select combination of the multiplexer is performed in a way that any transitional address value for the multiplexer leads to a monotonic change of the output of the multiplexer, and voltage pulses are the output of the multiplexer. The voltage pulses are then converted to current pulses using a plurality of resistors, operational amplifiers, and capacitors in Step 630. The method 600 can further include Steps 640 and 650. In Step 640, a charge booster circuit is used to minimize overshoots and undershoots, the charge booster circuit. The charge booster circuit includes an operational amplifier, a plurality of resistors, and a capacitor. In Step 650, a charge flowing through the capacitor is controlled using the resistors to match a charge needed to bring the voltage across a parasitic capacitor of the test circuit to provide an output of the charge booster circuit to the DUT.

Although only a few embodiments have been described in detail, it should be appreciated that the invention may be implemented in many other forms without departing from the scope of the invention. In view of all of the foregoing, it should be apparent that the present embodiments are illustrative and not restrictive and the invention is not limited to the details given herein, but may be modified within the scope and equivalents of the appended claims.

What is claimed is:

1. A test circuit for applying current pulses to a device under test (DUT), the test circuit comprising:
a multiplexer that outputs analog voltage pulses, the multiplexer being capable of generating both bipolar and unipolar voltage pulses; and
at least one operational amplifier and resistor that receive the voltage pulses from the multiplexer and convert the voltage pulses to current pulses, wherein an operational amplifier outputs current pulses, wherein the current pulses are bipolar or unipolar current pulses depending on whether the at least one operational amplifier and resistor receive bipolar or unipolar voltage pulses.

2. The test circuit of claim 1, further comprising a charge booster circuit for minimizing overshoots and undershoots during transitions between current levels, wherein the charge booster circuit receives the current pulses as its input and the charge booster circuit delivers its output to the DUT, wherein the DUT is positioned between ground and the output of the current pulses.

3. The test circuit of claim 2, wherein the charge booster circuit comprises at least one operational amplifier and a plurality of resistors.

4. The test circuit of claim 2, wherein the charge booster circuit comprises at least one operational amplifier and a bank of four switched resistors and one fixed resistor.

5. The test circuit of claim 1, wherein the multiplexer has one less input select line than voltage levels provided to its input terminals.

6. The test circuit of claim 5, wherein the multiplexer has three voltage levels provided to four input terminals.

7. The test circuit of claim 6, wherein an intermediate voltage level is selected with a transitional address for an input select combination of the multiplexer, wherein the input select combination comprises address values assigned to the input select lines.

8. The test circuit of claim 5, wherein only one input select address line changes during a transition from highest voltage to intermediate voltage or from lowest voltage to intermediate voltage.

9. The test circuit of claim 1, wherein the multiplexer generates an analog signal from discrete voltages.

10. The test circuit of claim 1, wherein at least two operational amplifiers and five resistors receive the voltage pulses from the multiplexer and convert the voltage pulses to current pulses.

11. A method of providing a pulsed current to a device under test (DUT), the method comprising:
providing a plurality of different voltage levels to a plurality of input terminals of a multiplexer;
generating voltage pulses from a selected voltage level by using input select combination of input select lines of the multiplexer to determine which of the input terminals of the multiplexer is connected to an output of the multiplexer, wherein input select combination of the multiplexer is performed by assigning address values to input select lines of the multiplexer in a way such that any transitional address value leads to a monotonic change of the output of the multiplexer, wherein the output of the multiplexer comprises voltage pulses; and
converting the voltage pulses to current pulses using a plurality of resistors, operational amplifiers, and capacitors.

12. The method of claim 11, wherein converting further comprises:
using a charge booster circuit to minimize overshoots and undershoots, the charge booster circuit comprising an operational amplifier, a plurality of resistors, and a capacitor.

13. The method of claim 12, wherein using the charge booster circuit comprises the charge booster circuit receiving the current pulses as its input and delivering its output to the DUT, wherein the DUT is positioned between ground and the output of the current pulses.

14. The method of claim 13, wherein using the charge booster circuit further comprises controlling a charge flowing through the capacitor using the plurality of resistors to match a charge needed to bring the voltage across a parasitic capacitor to provide an output of the charge booster circuit to the DUT.

15. A single circuit capable of providing both unipolar and bipolar current pulses, the circuit comprising:
a muiltiplexer that receives at least one positive voltage signal and at least one negative voltage signal, wherein the multiplexer is capable of generating both bipolar and unipolar voltage pulses from the voltage signals it receives; and
at least one operational amplifier and resistor that receive the voltage pulses from the multiplexer and convert the voltage pulses to current pulses, wherein an operational amplifier outputs bipolar or unipolar current pulses depending on whether the at least one operational amplifier and resistor receive bipolar or unipolar voltage pulses.

16. The circuit of claim 15, wherein at least two operational amplifiers and five resistors that receive the voltage pulses from the multiplexer and convert the voltage pulses to current pulses.

17. A method of using a charge booster circuit for minimizing overshoots and undershoots during transitions between current levels in a test circuit for applying current pulses to a device under test (DUT), the method comprising:
providing the test circuit including a charge booster circuit, the charge booster circuit comprising at least one operational amplifier, a resistor network, and a capacitor;
inputting current pulses to the charge booster circuit;
controlling a charge flowing through the capacitor using the resistor network to match a charge needed to bring voltage across a parasitic capacitor of the test circuit to provide an output of the charge booster circuit; and
delivering the output of the charge booster circuit to the DUT.

18. The method of claim 17, further comprising converting voltage pulses to the current pulses using at least one operational amplifier and resistor before inputting the current pulses to the charge booster circuit.

19. The method of claim 18, further comprising receiving the voltage pulses from a multiplexer before converting the voltage pulses to current pulses.

20. The method of claim 19, wherein the multiplexer has one less input select line than voltage levels provided to its input terminals.
